(19) United States
(12) Patent Application Publication
(10) Pub. No.: US 2024/0113701 A1
(43) Pub. Date: Apr. 4, 2024

(54) SEMICONDUCTOR DEVICE

(71) Applicant: LAPIS Technology Co., Ltd., Yokohama-shi (JP)

(72) Inventor: Takuya MATSUMOTO, Yokohama-shi (JP)

(73) Assignee: LAPIS Technology Co., Ltd., Yokohama-shi (JP)

(21) Appl. No.: 18/472,335

(22) Filed: Sep. 22, 2023

(30) Foreign Application Priority Data
Sep. 29, 2022 (JP) 2022-157097

(51) Int. Cl. H03K 5/15; H03K 5/133

(52) U.S. Cl. CPC H03K 5/15073; H03K 5/133; H03K 2005/00058

(57) ABSTRACT

A semiconductor device configured by bonding a first and a second chip together, including: a first signal output circuit provided at both the first and the second chip and driven by a first drive power; a second signal output circuit provided at both the first and the second chip and driven by a second drive power; a first phase comparison circuit, provided at the first chip, that compares a phase of a first signal and a second signal; a second phase comparison circuit that is provided at the second chip, and that compares a phase of a third signal and a fourth signal; a third phase comparison circuit, provided at the first chip, that compares a phase of a fifth signal and a sixth signal; and a fourth phase comparison circuit, provided at the second chip, that compares a phase of a seventh signal and an eighth signal.

### CROSS-REFERENCE TO RELATED APPLICATION

This application claims priority under 35 USC 119 from Japanese Patent Application No. 2022-157097, filed on Sep. 29, 2022, the disclosure of which is incorporated by reference herein.

### BACKGROUND

### Technical Field

The present disclosure relates to an semiconductor device.

### Related Art

A semiconductor device disclosed in Japanese Patent Application Laid-Open (JP-A) No. 2013-089001, is configured by plural controlled chips stacked on a control chip, and a delay time is detected by comparing a phase difference between chips using a phase comparison circuit.

However, in the above conventional semiconductor devices, differences in delay time between chips due to differences in drive power when driving signal output circuits, have not been considered.

### SUMMARY

The present disclosure is to provide a semiconductor device that may determining a difference in delay time between chips due to differences in drive power when driving signal output circuits.

A first aspect of the present disclosure is a semiconductor device configured by bonding a first chip and a second chip together, the semiconductor device including: a first signal output circuit provided at both the first chip and the second chip and driven by a first drive power; a second signal output circuit provided at both the first chip and the second chip and driven by a second drive power different from the first drive power; a first phase comparison circuit, provided at the first chip, which compares a phase of a first signal with a phase of a second signal, wherein: the first signal is output from the first signal output circuit provided at the first chip and input directly to the first phase comparison circuit, and the second signal is output from the first signal output circuit provided at the first chip and input to first phase comparison circuit the via the first signal output circuit provided at the second chip; a second phase comparison circuit that is provided at the second chip, and that compares a phase of a third signal with a phase of a fourth signal, wherein: the third signal is output from the first signal output circuit provided at the first chip, transmitted to the second chip, and input directly to the second phase comparison circuit, and the fourth signal is output from the first signal output circuit provided at the first chip, transmitted to the second chip, and input to the second phase comparison circuit via the first signal output circuit provided at the second chip; a third phase comparison circuit, provided at the first chip, that compares a phase of a fifth signal with a phase of a sixth signal, wherein: the fifth signal is output from the second signal output circuit provided at the first chip and input directly to the third phase comparison circuit, and the sixth signal is output from the second signal output circuit provided at the first chip and input to the third phase comparison circuit via the second signal output circuit provided at the second chip; and a fourth phase comparison circuit, provided at the second chip, that compares a phase of a seventh signal with a phase of an eighth signal, wherein: the seventh signal is output from the second signal output circuit provided at the first chip and transmitted to the second chip, and input directly to the fourth phase comparison circuit, and the eighth signal is output from the second signal output circuit provided at the first chip and transmitted to the second chip, and input to the fourth phase comparison circuit via the second signal output circuit provided at the second chip after being.

In a second aspect of the present disclosure, in the above first aspect, may further include: a first delay time computation section that uses the comparison result of the first phase comparison circuit and the comparison result of the second phase comparison circuit, to compute a delay time when output signals of the first signal output circuits move between the first chip and the second chip; and a second delay time computation section that uses the comparison result of the third phase comparison circuit and the comparison result of the fourth phase comparison circuit, to compute delay times when output signals of the second signal output circuits move between the first chip and the second chip.

In a third aspect of the present disclosure, in the above first aspect, the first chip and the second chip may be bonded together by die-to-wafer bonding.

In a fourth aspect of the present disclosure, in the above second aspect, the first chip and the second chip may be bonded together by die-to-wafer bonding.

In a fifth aspect of the present disclosure, in the above aspects, in a case in which three or more types of signal output circuits having different respective drive powers are provided at both the first chip and the second chip, a signal output circuit driven by a minimum drive power may serve as one of the first signal output circuit or the second signal output circuit, and a signal output circuit driven by a maximum drive power may serve as the other of the first signal output circuit or the second signal output circuit.

According to the above aspects, the semiconductor device of the present disclosure may determine a difference in delay time between chips due to differences in drive power when driving signal output circuits.

### BRIEF DESCRIPTION OF THE DRAWINGS

Exemplary embodiments will be described in detail based on the following figures, wherein:

FIG. 1 is a diagram illustrating a schematic configuration of a semiconductor device of an exemplary embodiment of the present disclosure;

FIG. 2 is a diagram illustrating a circuit configuration of the above semiconductor device; and

FIG. 3 is a graph illustrating a relationship between drive power needed to drive a signal output circuit and a delay time accompanying movement between chips of a signal output from signal output circuits.

### DETAILED DESCRIPTION

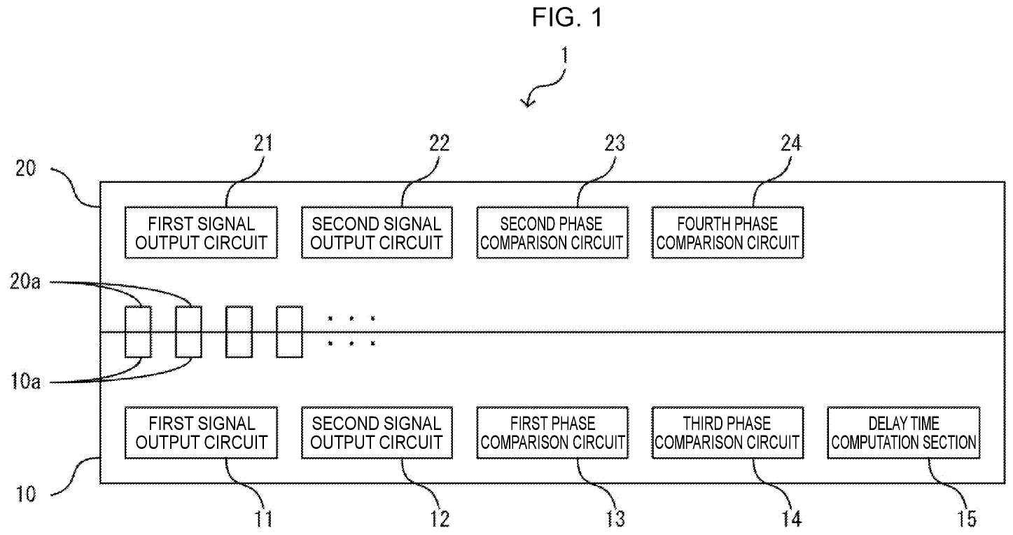

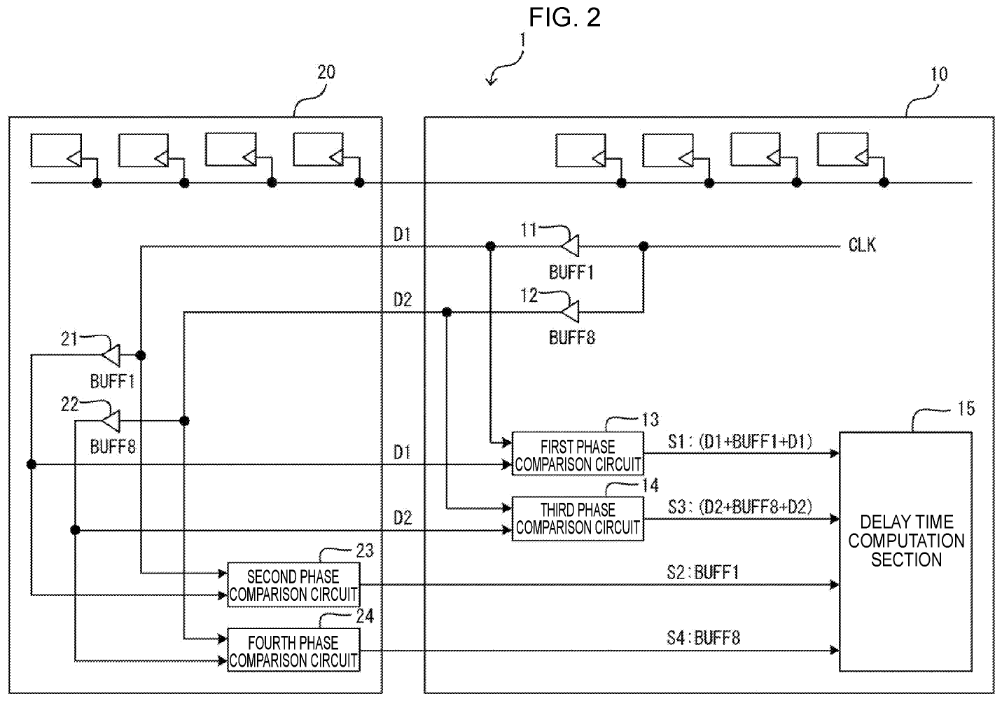

Next, description follows regarding an exemplary embodiment of the present disclosure, with reference to the drawings. FIG. 1 is a diagram illustrating a schematic configuration of a semiconductor device 1 of an exemplary embodiment of the present disclosure. FIG. 2 is a diagram illustrating a circuit configuration of the semiconductor device 1.

As illustrated in FIG. 1 and FIG. 2, the semiconductor device 1 is configured by a first chip 10 and a second chip 20 bonded together by die-to-wafer bonding. The die-to-wafer bonding means that the first chip 10 and the second chip 20 are stacked and also in a bonded state in which plural metal pads 10a formed on the first chip 10 are respectively in direct contact with plural metal pads 20a formed on the second chip 20.

The semiconductor device 1 includes a first signal output circuit 11, a second signal output circuit 12, a first phase comparison circuit 13, a third phase comparison circuit 14, and a delay time computation section 15 provided at the first chip 10, and a first signal output circuit 21, a second signal output circuit 22, a second phase comparison circuit 23, and a fourth phase comparison circuit 24 provided at the second chip 20.

The first signal output circuits 11, 21 are driven by a first drive power. The second signal output circuits 12, 22 are driven by a second drive power different to the first drive power. The first signal output circuits 11, 21 and the second signal output circuits 12, 22 are circuits that perform a given processing on an input signal before output and, for example, may be a buffer circuit, an inverter circuit, a flip-flop circuit, or the like.

In the present exemplary embodiment, for example, the first signal output circuits 11, 21 are buffer circuits, and the second signal output circuits 12, 22 are octal buffer circuits. In such cases, the second drive power needed to drive the second signal output circuits 12, 22 is higher than the first drive power needed to drive the first signal output circuits 11, 21.

The first phase comparison circuit 13 is provided at the first chip 10, and detects a delay time between two signals by comparing a phase of a first signal with a phase of a second signal. The first signal is a signal that is output from the first signal output circuit 11 provided at the first chip 10 and input directly to the first phase comparison circuit 13 in the first chip 10. The second signal is a signal that is output from the first signal output circuit 11 provided at the first chip 10 and input to the first phase comparison circuit 13 via the first signal output circuit 21 provided at the second chip 20.

The second phase comparison circuit 23 is provided at the second chip 20, and detects a delay time between two signals by comparing a phase of a third signal with a phase of a fourth signal. The third signal is a signal that is output from the first signal output circuit 11 provided at the first chip 10 and transmitted to the second chip 20, and input directly to the second phase comparison circuit 23 in the second chip 20. The fourth signal is a signal that is output from the first signal output circuit 11 provided at the first chip 10, transmitted to the second chip 20, and input to second phase comparison circuit 23 via the first signal output circuit 21 provided at the second chip 20.

The third phase comparison circuit 14 is provided at the first chip 10 and detects a delay time between two signals by comparing a phase of a fifth signal with a phase of a sixth signal. The fifth signal is a signal that is output from the second signal output circuit 12 provided at the first chip 10 and input directly to the third phase comparison circuit 14 in the first chip 10. The sixth signal is a signal output from the second signal output circuit 12 provided at the first chip 10, and input to the third phase comparison circuit 14 via the second signal output circuit 22 provided at the second chip 20.

The fourth phase comparison circuit 24 is provided at the second chip 20 and detects a delay time between two signals by comparing a phase of a seventh signal with a phase of an eight signal. The seventh signal is a signal that is output from the second signal output circuit 12 provided at the first chip 10, transmitted to the second chip 20, and input directly to the fourth phase comparison circuit 24 in the second chip 20. The eight signal is a signal that is output from the second signal output circuit 12 provided at the first chip 10, transmitted to the second chip 20, and input to the fourth phase comparison circuit 24 via the second signal output circuit 22 provided at the second chip 20.

The delay time computation section 15 functions as a first delay time computation section that uses the comparison result of the first phase comparison circuit 13 and the comparison result of the second phase comparison circuit 23 to compute a delay time when output signals of the first signal output circuits 11, 21, move between the first chip 10 and the second chip 20. Further, the delay time computation section 15 functions as a second delay time computation section that uses the comparison result of the third phase comparison circuit 14 and the comparison result of the fourth phase comparison circuit 24 to compute a delay time when output signals of the second signal output circuits 12, 22, move between the first chip 10 and the second chip 20.

Next, detailed description follows regarding computation of delay times in the semiconductor device 1 of the present exemplary embodiment.

As illustrated in FIG. 2, BUFF1 is a delay time of the buffer circuits of the first signal output circuits 11, 21, and D1 is a delay time accompanying movement between chips of the first chip 10 and the second chip 20 for signals output from the first signal output circuits 11, 21.

Moreover, BUFF8 is a delay time of the 8-level buffer circuits of the second signal output circuits 12, 22, and D2 is a delay time accompanying movement between chips of the first chip 10 and the second chip 20 for signals output from the second signal output circuits 12, 22.

In such cases, a delay time of an amount (D1+BUFF1+D1) is detected by the first phase comparison circuit 13, and a delay time of an amount BUFF1 is detected by the second phase comparison circuit 23.

The delay time computation section 15 is able to compute the delay time D1 accompanying movement between chips of the signals output from the first signal output circuits 11, 21, based on the following Equation (1). Here, S1 denotes the delay time detected by the first phase comparison circuit 13, and S2 denotes the delay time detected by the second phase comparison circuit 23.

D1=(S1−S2)/2 Equation (1)

Moreover, a delay time of an amount (D2+BUFF8+D2) is detected in the third phase comparison circuit 14, and a delay time of an amount BUFF8 is detected in the fourth phase comparison circuit 24.

The delay time computation section 15 is able to compute a delay time D2 accompanying movement between chips of signals output from the second signal output circuits 12, 22, based on following Equation (2). Here, S3 denotes a delay time detected by the third phase comparison circuit 14, and S4 denotes a delay time detected by the fourth phase comparison circuit 24.

D2=(S3−S4)/2 Equation (2)

### Modified Examples

In a case in which three of more types of signal output circuit having different respective drive powers are provided at both the first chip 10 and the second chip 20, a signal output circuit driven by a minimum drive power thereof may serve as one circuit from out of the first signal output circuit or the second signal output circuit, and the signal output circuit driven by a maximum drive power thereof may serve as the other circuit from out of the first signal output circuit or the second signal output circuit.

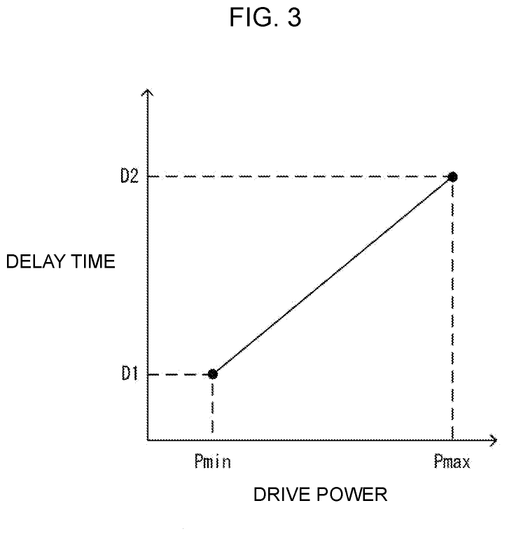

FIG. 3 is a graph illustrating a relationship between drive power needed to drive signal output circuits and a delay time accompanying movement between chips of signals output from signal output circuits.

As illustrated in FIG. 3, the delay time D1 accompanying movement between chips of a signal output from the signal output circuit driven by a minimum drive power Pmin is acquired, and the delay time D2 accompanying movement between chips of a signal output from the signal output circuit driven by a maximum drive power Pmax is acquired. Then a delay time accompanying movement between chips of a signal output from a signal output circuit driven by a drive power between these two drive powers can be estimated by linear interpolation between these two drive powers.

Moreover, there is no limitation to die-to-wafer bonding the first chip 10 and the second chip 20, and another type of bonding may be employed.

Moreover, although in the exemplary embodiment described above the delay time computation section 15 is provided at the first chip 10, the delay time computation section 15 may be provided at the second chip 20, or may be provided outside the semiconductor device 1.

Moreover, although in the exemplary embodiment described above a configuration is adopted such that a single delay time computation section 15 functions as both the first delay time computation section and the second delay time computation section, the first delay time computation section and the second delay time computation section may be configured separately to each other.

What is claimed is:

1. A semiconductor device configured by bonding a first chip and a second chip together, the semiconductor device comprising:
a first signal output circuit provided at both the first chip and the second chip and driven by a first drive power;
a second signal output circuit provided at both the first chip and the second chip and driven by a second drive power different from the first drive power;
a first phase comparison circuit, provided at the first chip, which compares a phase of a first signal with a phase of a second signal, wherein:
the first signal is output from the first signal output circuit provided at the first chip and input directly to the first phase comparison circuit, and
the second signal is output from the first signal output circuit provided at the first chip and input to first phase comparison circuit the via the first signal output circuit provided at the second chip;
a second phase comparison circuit that is provided at the second chip, and that compares a phase of a third signal with a phase of a fourth signal, wherein:
the third signal is output from the first signal output circuit provided at the first chip, transmitted to the second chip, and input directly to the second phase comparison circuit, and
the fourth signal is output from the first signal output circuit provided at the first chip, transmitted to the second chip, and input to the second phase comparison circuit via the first signal output circuit provided at the second chip;
a third phase comparison circuit, provided at the first chip, that compares a phase of a fifth signal with a phase of a sixth signal, wherein:
the fifth signal is output from the second signal output circuit provided at the first chip and input directly to the third phase comparison circuit, and
the sixth signal is output from the second signal output circuit provided at the first chip and input to the third phase comparison circuit via the second signal output circuit provided at the second chip; and
a fourth phase comparison circuit, provided at the second chip, that compares a phase of a seventh signal with a phase of an eighth signal, wherein:
the seventh signal is output from the second signal output circuit provided at the first chip and transmitted to the second chip, and input directly to the fourth phase comparison circuit, and
the eighth signal is output from the second signal output circuit provided at the first chip and transmitted to the second chip, and input to the fourth phase comparison circuit via the second signal output circuit provided at the second chip after being.

2. The semiconductor device of claim 1, further comprising:
a first delay time computation section that uses the comparison result of the first phase comparison circuit and the comparison result of the second phase comparison circuit, to compute a delay time when output signals of the first signal output circuits move between the first chip and the second chip; and
a second delay time computation section that uses the comparison result of the third phase comparison circuit and the comparison result of the fourth phase comparison circuit, to compute delay times when output signals of the second signal output circuits move between the first chip and the second chip.

3. The semiconductor device of claim 1, wherein the first chip and the second chip are bonded together by die-to-wafer bonding.

4. The semiconductor device of claim 2, wherein the first chip and the second chip are bonded together by die-to-wafer bonding.

5. The semiconductor device of claim 1, wherein, in a case in which three or more types of signal output circuits having different respective drive powers are provided at both the first chip and the second chip:
a signal output circuit driven by a minimum drive power serves as one of the first signal output circuit or the second signal output circuit, and
a signal output circuit driven by a maximum drive power serves as the other of the first signal output circuit or the second signal output circuit.
